(19) United States
(12) Patent Application Publication
(10) Pub. No.: US 2003/0130129 A1
(43) Pub. Date: Jul. 10, 2003

(54) Vacuum processing for fabrication of superconducting films fabricated by metal-organic processing

(75) Inventors: Igor Seleznev, Cambridge, MA (US); Michael J. Cima, Cambridge, MA (US)

Correspondence Address: Valarie B. Rosen, Choate, Hall & Stewart, Exchange Place, 53 State Street, Boston, MA, 02109, US

(73) Assignee: Massachusetts Institute of Technology

(21) Appl. No.: 10/194,561

(22) Filed: Jul. 13, 2002

Related U.S. Application Data
(60) Provisional application No. 60/305,407, filed on Jul. 13, 2001.

(51) Int. Cl. H01B 1/00; C10F 5/00; C04B 2/00; H01F 1/00; B32B 1/00; H01B 12/00; H01F 6/00; H01L 39/00; C23C 2/00; C01F 1/00; C25D 1/00; B23K 1/00; H01L 39/24

(52) U.S. Cl. 505/230; 505/238; 505/512; 505/470; 505/445; 505/446; 505/447

(57) ABSTRACT

A method of producing an oriented oxide superconducting film. A metal oxyfluoride film is provided on a substrate. The metal oxyfluoride film comprises the constituent metallic elements of an oxide superconductor in substantially stoichiometric proportions. The film is then converted into the oxide superconductor in a processing gas having a total pressure less than atmospheric pressure.

This application claims the priority of Provisional Patent Application No. 60/305,407, filed Jul. 13, 2001, the entire contents of which are incorporated by reference herein.

### FIELD OF THE INVENTION

This invention pertains to high temperature conversion of superconducting thin films, and, more specifically, to vacuum-based processing techniques for production of superconducting films exhibiting increased uniformity.

### BACKGROUND OF THE INVENTION

Superconducting thin films may be deposited on buffered or unbuffered substrates to form coated conductors. Such films can be produced by a variety of techniques, including sol-gel, metal-organic deposition using tri-fluoroacetates, co-evaporation of BaF₂ and metal/metal oxides, pulsed laser deposition, etc. However, many rare earth superconductors, such as YBCO, are anisotropic, and their superconducting properties are degraded by microstructural inhomogeneities. Preferably, YBCO thin films are fabricated with a c-axis orientation. YBCO grains with an a-axis orientation exhibit high angle grain boundaries with surrounding c-axis grains that perturb superconducting current and limit current density in the film.

Superconductor precursors deposited using metal-organic deposition techniques may be converted to the superconducting ceramic by high temperature conversion in an oxidizing atmosphere (Chan, et al., Appl. Phys. Lett., 1988, 53:1443). It is preferable that different regions of the film convert at approximately the same rate and time. If conversion is not uniform, some regions of the film may not convert to the ceramic, resulting in non-superconducting islands within the film. Alternatively, some regions of the film may be held too long at elevated temperatures following conversion. Ripening, oxidation/corrosion, and other aging processes may decrease the uniformity of the microstructure and degrade the superconducting properties of the final product. Accordingly, it is desirable to develop a processing protocol that facilitates uniform conversion of the superconductor precursor.

Thicker oxide superconductor coatings are preferred in applications requiring high current carrying capability, e.g., power transmission and distribution lines, transformers, fault current limiters, magnets, motors and generators. Thicker oxide superconducting films can achieve a higher effective critical current (Jc), that is, the total current carrying capability divided by the total cross sectional area of the conductor including the substrate. However, processing times increase as the films become thicker. Thus, it is desirable to increase the conversion rate of superconductor precursor films. Reduction in processing times not only reduces the consumption of high-purity processing gases but also capital costs. Where long tapes are produced by passing them through a furnace, decreased processing times allows the production of smaller furnaces. This reduces construction costs and the footprint of the apparatus.

### SUMMARY OF THE INVENTION

In one aspect, the invention is a method of producing an oriented oxide superconducting film. A metal oxyfluoride film is provided on a substrate. The metal oxyfluoride film comprises the constituent metallic elements of an oxide superconductor in substantially stoichiometric proportions. The film is then converted into the oxide superconductor in a processing gas having a total pressure less than atmospheric pressure. The total pressure may be less than or equal to about 80 Torr, about 8 Torr, about 1 Torr, about 0.1 Torr, about 0.01 Torr, or about 0.001 Torr. The processing gas may substantially consist of water vapor and oxygen. A buffer layer, for example, yttria stabilized zirconia, lanthanum aluminide, strontium titanate, ceria, yttria, or magnesium oxide, may be deposited on the substrate between the substrate and the metal oxyfluoride film. The film may be at least 0.3 μm thick, at least 0.5 μm thick, at least 0.8 μm thick, or at least 1 μm thick. The oxide superconductor may comprise YBCO. The substrate may comprise a ceramic, for example, yttria stabilized zirconia, lanthanum aluminide, strontium titanate, ceria, or magnesium oxide. In an alternative embodiment, the substrate comprises a metal, for example, steel, nickel, iron, molybdenum, copper, silver, or alloys or mixtures thereof The metal may be untextured, uniaxially textured, or biaxially textured. The critical current density Jc of the film may be greater than 0.45 MA/cm², greater than 1 MA/cm², greater than 2 MA/cm², or greater than 4 MA/cm².

In an alternative embodiment, conversion of the metal oxyfluoride is initiated in a processing gas having a moisture content of less than 1% by mass and a pressure less than atmospheric pressure for a time sufficient to form a layer of the oxide superconductor at the substrate/film interface. For example, the partial pressure of water may be 10 mTorr or less and the total pressure 8 Torr or less. The moisture content of the processing gas is then increased, and conversion is completed. For example, the partial pressure of water may be increased to between 150 and 350 mTorr, while the total pressure is maintained at 8 Torr or less. The processing gas may consist substantially of water vapor and oxygen.

In anther aspect, the invention is a c-axis textured superconducting oxide film fabricated by the above methods.

### BRIEF DESCRIPTION OF THE DRAWINGS

The invention is described with reference to the several figures of the drawing in which:

FIG. 1A depicts a schematic of a oxide superconducting film prepared according to an embodiment of the invention;

FIG. 1 depicts a heating profile for a low temperature heat treatment according to one embodiment of the invention;

FIG. 2 is a schematic of a prototype system design for conversion at low pressures;

FIG. 3 is an electron micrograph of an YBCO film prepared at 725° C. and constant PH₂O of 6-10 Torr;

FIG. 4 is an X-ray diffraction pattern of a YBCO sample processed at 725° C., P=58 Torr and without added moisture;

FIG. 5 is an X-ray diffraction pattern of a sample converted under base pressure of 70 Torr, 15 minutes at low PH2O, 12 min at high PH₂O (10 Torr) and 785° C.;

FIG. 6 is a micrograph of an YBCO film produced using a low/high treatment according to an embodiment of the invention;

FIG. 7 shows a Tc measurement of an YBCO sample produced at 785° C., 70 Torr base pressure, 15 minutes at low PH₂O (Onset is 93 K and Tc is 91.9 K);

FIG. 8 is a micrograph of a lm thick YBCO film converted at 785° C., PO_{2=0.76} Torr, 15 minutes at low PH2O, 30 minutes at PH2O=10 Torr, and 70 Torr base pressure;

FIG. 9 is a micrograph of a thick YBCO film converted at base pressure of 16 Torr;

FIG. 10 is a lower magnification micrograph of the sample shown in FIG. 9;

FIG. 11 is a micrograph showing blocks of a-axis grains in the film depicted in FIG. 9;

FIG. 12 is a schematic of a Rapid Thermal Anneal furnace for use with the invention;

FIG. 13 is a micrograph of a 0.03 μm thick YBCO film deposited on LAO (935° C., PO₂=7.6 Torr, P=7.6 Torr, 5 min. at PH₂O=350 mTorr);

FIG. 14A is a micrograph of a 0.08 μm thick YBCO film deposited on YSZ without using a low/high protocol (835° C., PO₂=7.75 Torr, 10 min. at PH₂O=350 mTorr);

FIG. 14B is a micrograph of a 0.8 μm thick YBCO film deposited on YSZ using a low/high protocol (835° C. PO₂=7.6 Torr, P=7.6 Torr, 2 min. at PH₂O=10 mTorr and 5 min. at PH₂O=300 mTorr); and

FIG. 15 is a micrograph of a 0.8 μm thick YBCO film deposited on nickel with an intervening buffer layer of yttria, yttrium stabilized zirconium (YSZ), and ceria using a low/high protocol (785° C. PO₂=1 Torr, P=1 Torr, 1 min. at PH₂O=5 mTorr and 3 min. at PH₂O=150 mTorr).

### DETAILED DESCRIPTION

The invention employs a vacuum-based processing route for fabrication of superconducting thin films. The process uses a fluorinated precursor that is deposited on a substrate, following which the coating is reacted to form a glassy oxyfluoride phase. This phase is then decomposed in a reduced pressure atmosphere to cause the formation of a superconducting film. We have demonstrated that diffusion of HF away from the surface of the film is the rate-limiting step during high temperature conversion of tri-fluoroacetate (TFA)—derived YBCO films for the processing conditions commonly used (i.e., atmospheric pressure). Uneven removal of HF causes non-uniform conversion of the film along the length of a sample. This effect may become particularly pronounced on long length samples where the concentration of HF gas above the surface may increase significantly during processing. Thus, uniform removal of HF gas from the surface facilitates the uniform growth of high quality films. An effective way to ensure uniform gas transport is to lower the ambient pressure in the furnace. The effective diffusion coefficient of the gaseous species becomes large, increasing transport away from the sample.

In addition to influencing conversion rates, HF also influences the microstructure of the sample. HF is reactive with many substrates and may etch the substrate surface, roughening the substrate. Unevenness of the substrate surface has been associated with the preferential development of a-axis texturing (McIntyre, et al., The Effects of Substrate Surface Steps on the Microstructure of Epitaxial YBa₂Cu₃O₇₋ₓ, Thin Films on (001) LaAlO₃, J Cryst. Growth, 1995, 149:64). Thus, increasing the dispersion of HF away from the substrate during conversion may reduce substrate etching and increase c-axis texturing in the converted film.

The processes of the invention result in rapid conversion of precursor films to superconductors exhibiting primarily c-axis texturing. As the terms are used herein, texturing and orientation indicate that a particular axis of the oxide superconductor is oriented perpendicular to the substrate. For example, the c-axis is perpendicular to the substrate in c-axis textured films and c-axis oriented grains, while the a and b-axes are parallel to the substrate. The a and b-axes in various grains may not necessarily be parallel to one another.

The techniques of the invention may be used for fabrication of any oxide superconductor. In one embodiment, the superconductor is YBa₂Cu₃O_{y} (YBCO), where y is typically about 6.8. One skilled in the art will understand that y will vary with the partial pressure of oxygen. One skilled in the art will recognize that other oxide superconductors will benefit from the teachings of the invention. For example, other rare earth elements may be substituted for yttrium in YBCO films. Exemplary rare earth elements include Nd, Sm, Ce, Eu, Gd, Dy, Ho, Er, Tm, Yb, Lu, La, Pr, and Pm. In addition to the 123 type YBCO ceramics produced above, both 124 and 247 ceramics may be produced with the techniques of the invention. These ceramics may also be doped with calcium. Other superconductors that may be fabricated through ex situ MOD techniques may also be fabricated using the techniques of the invention. Exemplary ceramics include BSSCO (bismuth, strontium, calcium, copper and oxygen) ceramics and TBSCCO and HBSCCO ceramics, in which barium and either thallium or mercury is substituted for bismuth. Both 2223 and 2212 BSSCO ceramics may be produced, as well as lead-doped BSCCO materials. Other ceramics that may be produced using the techniques of the invention include La₂₋ₓMₓCuO₄, where M is Ba or Sr, and La₂₋ₓSrₓCaCuO₄.

One skilled in the art will recognize that polycrystalline metallic substrates are preferred for industrial applications. Such substrates may be textured or untextured, depending on the application and the lattice constant of the metal. In one embodiment, the metal substrates have a crystallographic plane whose lattice size matches that of the superconducting oxide or an intervening buffer layer within at least 10-20%. Alternatively, the substrate may be deformation textured. Preferably, metallic substrates are biaxially textured to provide a surface that is lattice matched to a buffer layer or the oxide superconductor. It may be desirable to use a buffer layer to prevent diffusion of the substrate metal into the oxide. Exemplary buffer layers include YSZ, LaAlO₃, SrTiO₃, Y₂O₃, CeO₂, and MgO, or combinations of these. Coatings between the metal and the buffer layer help compensate for any lattice mismatch and prevent diffusion of the metal into the ceramic. In addition, the metal should be sufficiently mechanically robust to be formed into tapes and wires and should not diffuse through the buffer layer during conversion. In a preferred embodiment, nickel is used as a substrate for the oxide superconductors of the invention. Other appropriate substrates include, without limitation, steel, nickel alloys, silver, and alloys of copper, iron, and molybdenum.

Appropriate ceramic substrates for the invention may be single crystalline or polycrystalline and should be lattice-matched, with a lattice constant similar to that of the oxide semiconductor. Exemplary ceramic substrates include, without limitation, YSZ, LaAlO₃, SrTiO₃, CeO₂, and MgO. A buffer layer may be used on these substrates if desired. As used herein, the term “substrate” refers to the material on which the precursor is deposited. The substrate may be an uncoated metal or ceramic base or include a buffer layer interposed between the base and the precursor.

The substrate may have any shape or structure and may be flat or three-dimensional. Exemplary shapes include tapes, wires, ribbons, coils, and sheets. The substrate may have macrostructural texture such as trenches or divots. One skilled in the art will recognize that the shape of the substrate is primarily limited by the ability to deposit the precursor on its surface. Use of liquid precursors enables the use of complicated geometries.

In one embodiment, the precursor is deposited on the substrate as a stoichiometric mixture of trifluoroacetate salts of the constituent metals. Such salts may be dissolved in organic solvents such as esters, ethers, and alcohols for deposition as a liquid. For example, the substrate may be coated by spinning, spraying, painting, or dipping the substrate into the precursor solution. Alternatively, the precursor may be deposited by chemical or physical deposition techniques, including but not limited to physical vapor deposition, chemical vapor deposition, or metal-organic CVD. It is proposed that conversion of YBCO films proceeds by conversion of BaF₂ to an oxide, followed by reaction with copper oxide and yttrium copper oxide to form YBCO. Thus, a precursor comprising BaF₂, Cu, and Y or copper and yttrium oxides may be deposited on the surface, for example, by evaporation, sputtering, e-beam evaporation, and laser ablation. Indeed, it is not necessary that the fluorine salt be with barium. Any component of the superconductor whose fluorine salt is unstable in the presence of water may be exploited as a fluoride in the precursor.

Following deposition of the precursor, it is decomposed at low temperatures (e.g., <400° C.) to form an intermediate metal oxyfluoride compound. The metal oxyfluoride is then converted into the tetragonal YBCO phase by reaction in a moist oxidizing atmosphere. The initial step is believed to be the reaction of the metal oxyfluoride precursor with water to form the corresponding metal oxides (CuO, BaO, and Y₂O₃) and HF gas. Removal of the HF from the film is the rate-limiting step in conversion to the final oxide superconductor product.

The present invention recognizes that it is possible to rapidly convert the metal oxyfluoride film into an oxide superconductor film under conditions, which will provide a highly oriented epitaxial film with high critical current density. According to the method of the invention, temperature and P_{H2O} conditions are selected and applied as described herein during the step of conversion of the metal oxyfluoride into an oxide superconductor to provide an oxide superconductor film having a thickness of greater than or equal to 0.5 μm, preferably greater than or equal to 0.8 μm and most preferably greater than or equal to 1.0 μm, and a critical current density of at least 10⁵ A/cm² and preferably at least 10⁶ A/cm². The oxide superconductor may be further characterized as having substantial c-axis epitaxial alignment. While a-axis texturing is undesirable, its presence in the films of the invention will not destroy their superconducting properties so long as there is a current path through the c-axis oriented grains across the sample. It is preferable to reduce the number density of a-axis oriented grains in a film

The improved electrical transport properties of the invention are achieved by processing the metal oxyfluoride film into an oxide superconductor under reaction conditions, which control the reaction kinetics of the process and the microstructure of the resultant oxide film. In particular, reaction conditions are selected which control the rate of consumption of BaF₂ and/or other metal fluorides and thus the HF evolution rate which among other effects permits sufficient time for the transport of HF from the film and which also reduces the HF concentration during the nucleation of the oxide superconductor layer at the substrate/film interface.

U.S. Pat. No. 6,172,009, entitled “Controlled conversion of metal oxyfluorides into superconducting oxides,” the entire contents of which are incorporated herein by reference, notes that moisture content, temperature, and PO₂ may all be controlled to manage reaction rates and microstructure. Reducing either temperature or PH₂O with reduce the conversion rate. The PO₂ is selected to maintain processing conditions in a regime where the superconductor product is thermodynamically stable. The appropriate temperature and PH₂O profile may vary with film thickness. One skilled in the art will recognize that the operating conditions may be easily optimized for various compositions and thicknesses of the precursor and final superconductor films.

The actual amount of moisture appropriate in the injected processing gas is a function of the reaction temperature and total pressure. For the operating pressures used in the examples, the PH2O is preferably between 150 mTorr, and 350 mTorr, which is about 35% of the atmosphere by mass at a total pressure of 1 Torr and about 4.4% of the atmosphere at a total pressure (P) of 8 Torr. During nucleation, it is preferably less than 10 mTorr, or 1% of the atmosphere by mass at a total pressure of 1 Torr. In alternative embodiments, the water partial pressure during nucleation and initial growth may be less than 5 mTorr or less than 1 mTorr. There may be a lower limit below which the reaction will not proceed spontaneously. As the total pressure is reduced below 1 Torr or 0.01 Torr, one skilled in the art will easily recognize when the amount of water available to the film during conversion is no longer sufficient. The exact value may be determined by reference to thermodynamic stability of the reactants or products. Alternatively, it may be determined empirically by lowering the P_{H2O} at a given temperature until the reaction no longer proceeds. Additionally, appropriate moisture levels, especially during the latter stages of conversion, may be well above such lower limits, since the processing time may be too long otherwise.

Likewise, the total amount of oxygen available to the film must be sufficient to thermodynamically favor the production of the desired oxide phase. The partial pressure of oxygen during conversion may be about 8 Torr or less, for example, 1 Torr or 0.3 Torr. The appropriate oxygen partial pressure may vary with the thickness of the film and the temperature during conversion.

### EXAMPLE

EXPERIMENTAL PROCEDURES

Preparation of Precursor

Circular wafers of LaAlO₃ (LAO) were received from a commercial vendor (Applied Technologies Enterprise, Irmo, S.C.). The wafers were diced into smaller (6.0 mm×6.0 mm) square pieces using a diamond-impregnated wire blade. We used square (001)-oriented LAO single crystal substrates and (100) oriented square (10 by 10 mm) yttria-stabilized zirconia (YSZ) single crystal substrates. An epitaxial buffer layer of 1000 μm of CeO₂ was sputtered onto YSZ substrates prior to spin coating. The buffer layer is necessary to prevent reactions between the substrate material and the YBCO coating during high temperature conversion. The single crystal substrates were cleaned in three successive solutions of chloroform, acetone and methanol using an ultrasonic bath. The substrates were examined after cleaning under optical microscope at 40-X and wiped with methyl alcohol.

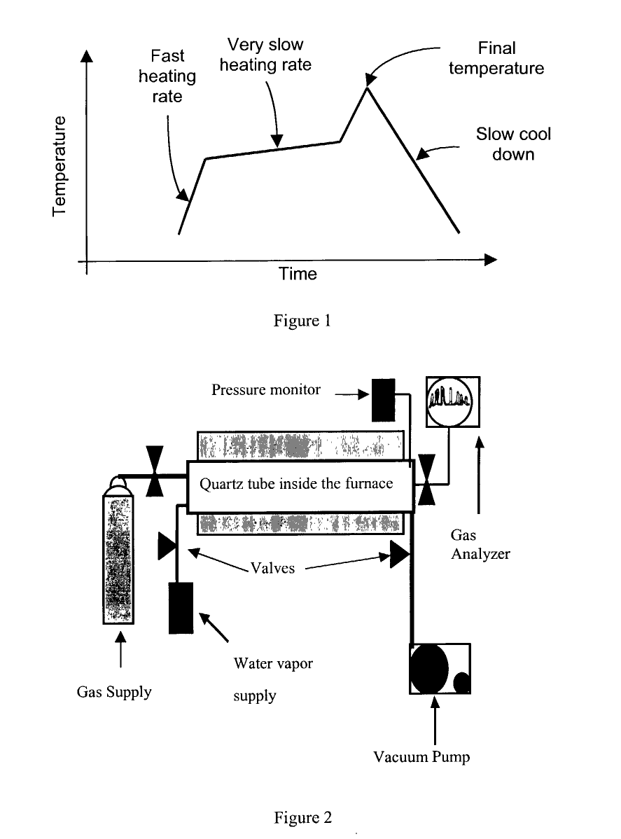

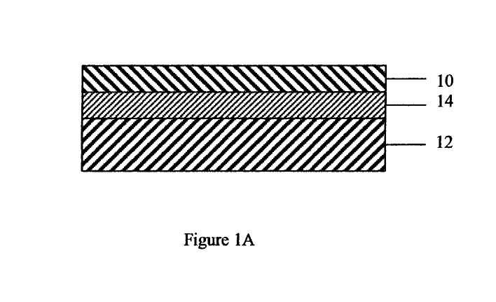

Textured Ni metal tape substrates were prepared using RABiTS™ technology (Rolling-Assisted Biaxially-Textured Substrates). RABiTS results in a roll-textured and annealed metal tape coated with one or more oxide, metal buffer, or conditioning layers (see U.S. Pat. Nos. 6,180,570 and 6,375,768, the contents of both of which are incorporated herein by reference). Three buffer layers, Y₂O₃, YSZ and CeO₂, were deposited on the metal under the YBCO to prevent reactions between YBCO and Ni. An exemplary film prepared according to the techniques of the invention is shown in FIG. 1A. A superconducting film 10 is deposited on a metal base 12 that has been coated with buffer layer 14.

A metal trifluoroacetate precursor for spin coating was prepared by reacting yttrium, barium, and copper acetates and trifluoroacetic acid in water. Acetates were added in stoichiometric cation ratio of 1:2:3, respectively. The solution was then dried to a glassy state and then redissolved in methanol. The methanol solution was spin-coated onto a lattice-matched substrate using a photoresist spin coater. Spin coating was performed in a particulate containment hood with the humidity substantially lower than 50% RH. The coater was operated at approximately 4000 rpm and 1000 rpm for 0.3 μm and 0.8 μm thick films, respectively, and an acceleration time of 0.4 s. The temperature in the hood during spin coating was in the range of 23-31° C. Samples were then placed in the processing zone of the furnace.

Following spin coating, the samples were subjected to a low temperature heat treatment. The sample temperature was increased to 195° C. in 1 hr., then increased to 220° C. at a ramp rate of 0.05 C/min., and finally heated to approximately 400° C. in 40 min.; after this heating segment, active heating was stopped. The furnace was then cooled in stagnant, humid oxygen. The temperature profile for this heat treatment is shown in FIG. 1. The gas was switched from dry to moist about 13 minutes after starting the initial heating segment to suppress volatilization of copper. The gas for the tube furnace was saturated to approximately 95-100% RH by bubbling the gas through a room temperature water reservoir. A volumetric flow rate of 10+−1 scfh was used for the dry O₂, and volumetric flow rate of 10+−1 scfh was used for the moist O₂.

High Temperature Vacuum Processing

The first series of samples were annealed in quartz tubes heated in CM 2200 horizontal furnaces. The samples were introduced into the furnace on a quartz plate. The temperature of the samples was measured using a K-type thermocouple sealed in a high-purity alumina tube. The tip of the alumina tube was placed a few millimeters downstream of the samples. To convert samples at low pressures, the quartz tube inside the furnace was connected to an oil vacuum pump (FIG. 2). The pressure inside the furnace was regulated by changing the rate of pumping and flow rate of the O₂/N₂ into the furnace. Both rates were controlled with manual valves. The pressure inside the furnace was measured by a Kurt J. Lesker diaphragm manometer. The partial pressure of water in the furnace was determined as a difference in pressures before and after introduction of moisture into the furnace. A Dycor quadrupole gas analyzer was used for measuring relative concentrations of gases inside the quartz chamber.

A Rapid Thermal Anneal (RTA) furnace (Process Products Corporation) was used for a second series of low-pressure conversion experiments (FIG. 12). The RTA furnace has many advantages over the tube furnace. The RTA furnace has fewer potential leaks and a better vacuum design. Different kinds of heating profiles can be explored, including very fast heating and cooling rates. The heating elements, quartz lamps, are placed outside the vacuum chamber. This prevents degradation of the heating elements in the humid, oxidative atmosphere of the conversion. Samples that were processed in the RTA furnace were placed on a silicon wafer. The wafer was heated by the quartz lamps and the temperature monitored with a K-type thermocouple placed under the wafer. Oxygen and water vapor were introduced separately to the RTA furnace. A round-bottom flask of water was connected to the furnace and heated to generate water vapor. The pressure in the chamber of the furnace was monitored by a MKS Baratron® type 122A absolute pressure gauge.

The only lower limit on processing pressures in the RTA furnace is the need to provide sufficient oxygen and water vapor for the conversion. In typical atmospheric pressure processing methods, an atmosphere containing about 0.01% to 10% oxygen (0.076 to 7.6 Torr partial pressure) is maintained during conversion, and these partial pressures may be used at lower total pressures. Alternatively, high vacuum conditions with very low pressures (<10⁻² or 10⁻⁴ Torr) may be used. Satisfactory conversion may be achieved in an atmosphere of only oxygen and water vapor. In one embodiment, the pressure is reduced to the desired pressure of oxygen within the system, following which the desired flow rate of water vapor is introduced.

Analysis

X-ray data were collected using Rigaku RU-200 rotating anode X-ray source diffractometer. We used accelerating voltage of 50 kV and emission current of 200 mA. Theta-two theta scans were made in a range of 5-100° 2-theta. A Hitachi S-530 scanning electron microscope was used to examine the sample surfaces.

OBSERVATIONS AND DISCUSSION

Diffusion of the gas away from the surface of the film is the rate-limiting step during the high temperature conversion of the TFA-derived films at atmospheric pressure. This processing condition causes non-uniform conversion of the film along the length of a sample. For example, in a series of samples oriented parallel to the direction of gas flow, the upstream samples exhibited a higher degree of conversion (>88%) after high temperature processing in a high humidity atmosphere (725° C., 17 Torr, 100 ppm O₂, 50 min). The downstream samples exhibited a higher concentration of fluorine (<76% conversion) after processing, and the edges of the samples exhibited lower fluorine content than the interior portions of the samples. Thus, uniform removal of the HF gas from the surface is correlated with uniform growth of high quality YBCO films.

There are several possible methods of removing HF from the surface. For example, the gas velocity through the furnace may be increased. High gas velocities will decrease the boundary layer thickness above the film surface and carry the HF quickly out of the furnace. This method wastes the high purity carrier gas and requires that the equipment be designed to distribute the gas flow evenly over the surface of the substrate. Another method is to lower the ambient pressure in the furnace. The effective diffusion coefficient of the gaseous species becomes large and transport away from the sample is increased.

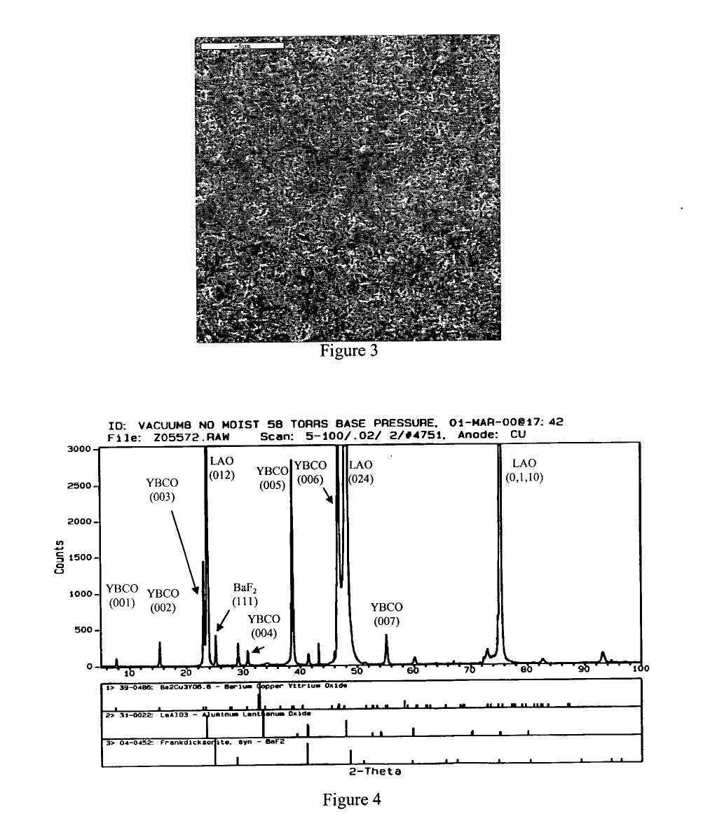

The first films prepared in the tube furnace were processed under conditions similar to those processed at atmospheric pressure (725° C., PO₂=0.076 Torr, PH₂O=6-10 Torr, total pressure (P)=77 Torr). A constant partial pressure of water was maintained during the conversion. Films prepared under these conditions had significant a-axis texture, as shown in FIG. 3. Conversion at 77 torr was complete in 10 to 15 minutes. The time of conversion was determined by x-ray analysis and by observations in the optical and electron microscopes. At atmospheric pressure, the conversion time of the 0.35 μm thick films was approximately 45 minutes. Thus, the application of vacuum during the high temperature conversion decreased the time for conversion by a factor of at least 3. This significantly reduces the quantity of gas used to process the sample. The high purity gases used during high temperature conversion are expensive, and the decrease in production time dramatically decreases the cost of producing the superconducting YBCO films.

An increase in conversion rate apparently caused a change in the growth mode of the film. Films grown under vacuum exhibited a-axis texture, but films of the same thickness that were grown under atmospheric pressure were textured along the c-axis. To increase the c-axis texturing, a low-high process was employed (Smith, et al., “High Critical Current Density Thick MOD-Derived YBCO Films”, IEEE Transactions on Applied Superconductivity, (1999) 9:1531-1534, the entire contents of which are incorporated herein by reference). The metal oxyfluoride film is processed in a low moisture environment for a time sufficient to nucleate and grow a thin layer of the oxide superconductor at the substrate/film interface. The precise thickness of this layer is not known; however, it is estimated to be on the order of a tenth to several hundredths of a micrometer thick. Thereafter, the amount of water vapor in the processing gas is increased. In one embodiment, the partial pressure is increased to the saturation point. The process is continued until conversion of the metal oxyfluoride into the oxide superconductor is complete. The subsequent increase in growth rate at higher PH₂O does not change the texture of the film. Smith, et al, reported that films produced by the low-high method had c-axis orientation and Jc values greater than 1 MA/cm². While not being bound by any particular mode of operation, the presence of the initial oxide superconducting layer may prevent substrate etching by HF retained in the film or above the substrate. Alternatively, the reduced HF content within the oxyfluoride film may favor c-axis texturing.

Mass spectroscopy was used to determine the moisture content inside the tube furnace. The water partial pressure inside the furnace was quite high even when no external water vapor source was applied. The furnace was originally designed for use at atmospheric pressure. Evidently, the rubber o-rings and vacuum grease seals were insufficient to seal the tube and the leaks under vacuum conditions introduced significant water vapor.

To evaluate whether the observed water partial pressure in the furnace was appropriate to simulate conditions of low moisture, we processed several samples without introducing any moisture (725° C., PO₂=0.058 Torr, P=58 Torr, 120 min.). FIG. 4 shows an x-ray pattern typical of these samples. Peaks of YBCO (001) in the XRD pattern show that, even without adding water to the system, growth of YBCO still occurs. Conversion of that sample was stopped after 120 minutes, but the BaF₂ (111) and (200) peaks were still present, indicating that conversion of the film was not complete. The speed of the conversion under these conditions was very low, and we used these conditions as a low moisture heat treatment.

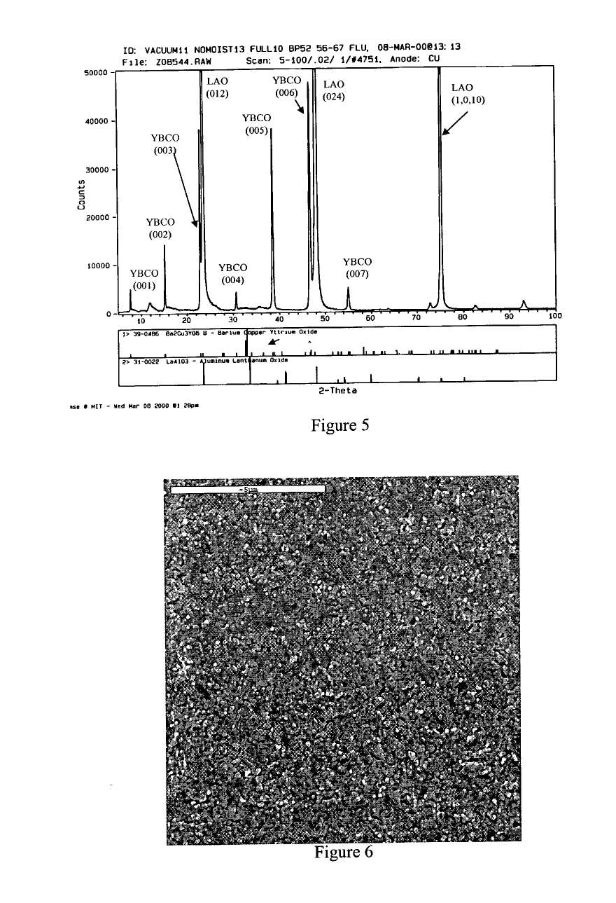

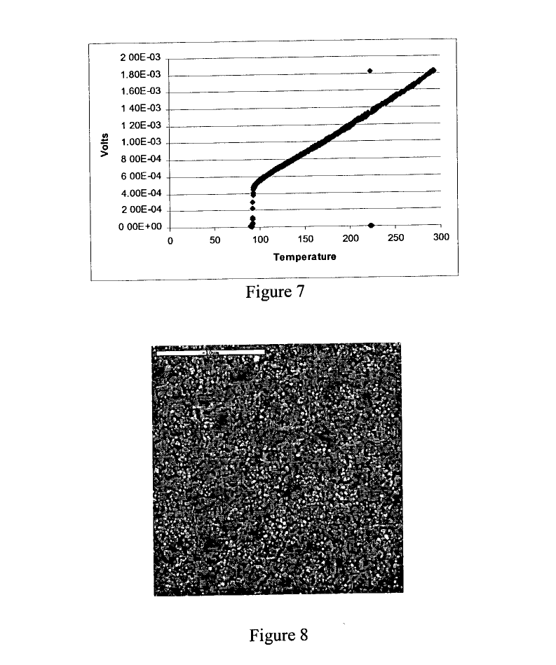

Several samples were converted using the low/high heat treatment under reduced pressure conditions (785° C., PO₂=0.7 Torr, P=70 Torr, 12 min. without added H₂O, and 15 min. at PH₂O=10 Torr). Samples that were produced using that heat treatment exhibited texturing along the c-axis (FIG. 5). A typical sample produced under these conditions is shown in FIG. 6. The sample had a Tc of 91.9 K and a Jc of 1.5 MA/cm₂.

A large number of thin film samples were converted using the low/high heat treatment protocol. Most of the samples exhibited c-axis texturing. The microstructure of these samples varied widely due to the difficulty of controlling the partial pressure of different gases in the furnace. Lowering the total pressure in the system increased the influence of vacuum leaks lead to increasing on the partial pressure of oxygen. In addition, the partial pressure of water fluctuated significantly during decomposition. Still, these experiments demonstrate that reduced growth rate during the initial stages of growth of YBCO films encourages development of c-axis texturing. These experiments also show that growth rate is an important parameter influencing the growth mode of the MOD-derived YBCO films.

THICK FILMS PRODUCED AT LOW PRESSURES

Conversion of 1 μm YBCO thick films with coatings of approximately 1 μm was also studied. Conditions similar to the conditions that were used for 0.35 μm films were initially used for conversion of 1 μm thick films (785° C., PO₂=0.7 Torr, P=70 Torr, 15 min. at low PH₂O, 20 min. at PH₂O=10 Torr). The thick film produced under these conditions exhibited primarily c-axis texturing (FIG. 8). Only an insignificant amount of a-axis texture is present in the film.

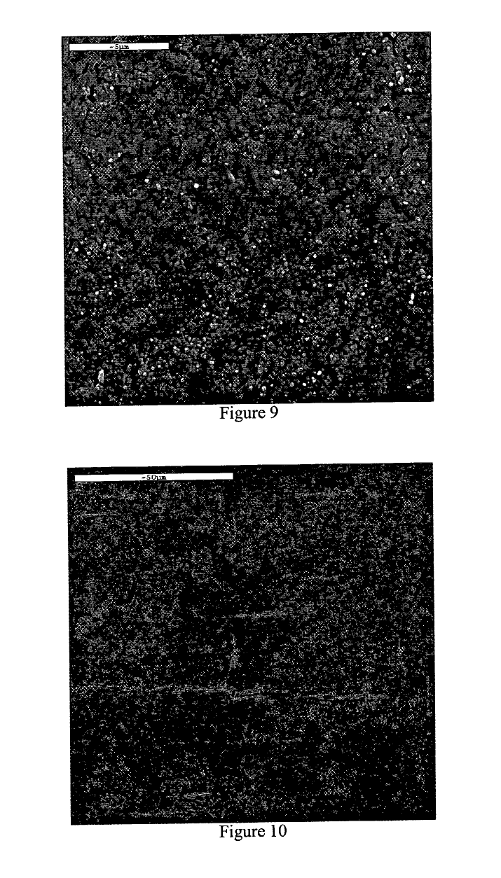

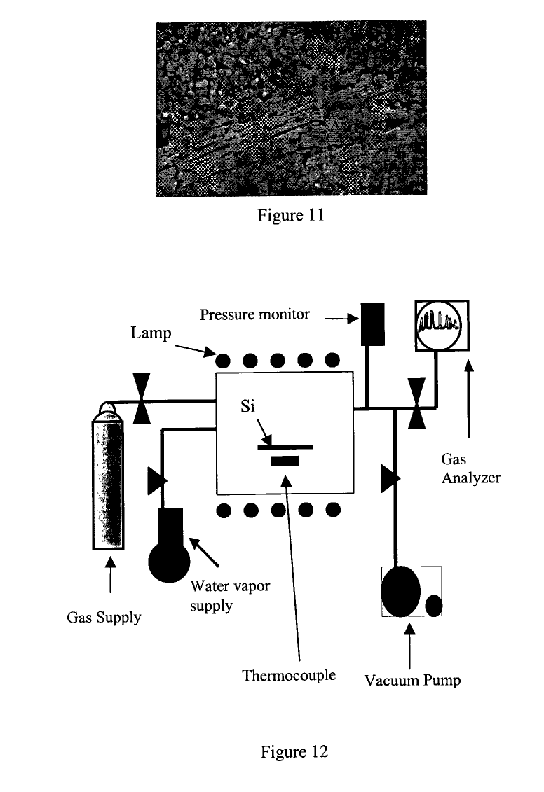

Conversion of another thick film (FIG. 9) was made at lower pressure (785° C., PO₂=0.76 Torr, P=16 Torr, 20 min. without added H₂O, 15 min. at PH₂O=34 Torr). Conversion of the film was completed in 35 minutes. Conversion of 1 μm thick films at 835° C. and atmospheric pressure takes about 1 hour. There is less a-axis texturing in the film than in the 1 μm film that was converted at 70 Torr (FIG. 8), but some perpendicular features can be observed at lower magnification, as shown in FIG. 10. The features indicated by white arrows in FIG. 10 were identified as blocks of grains oriented along the a-axis. The microstructure of these blocks is shown in FIG. 11. It is unclear why the a-axis texture had the observed distribution. It is possible that the single crystal substrate had some defects at the surface that caused preferential nucleation of the a-axis oriented grains.

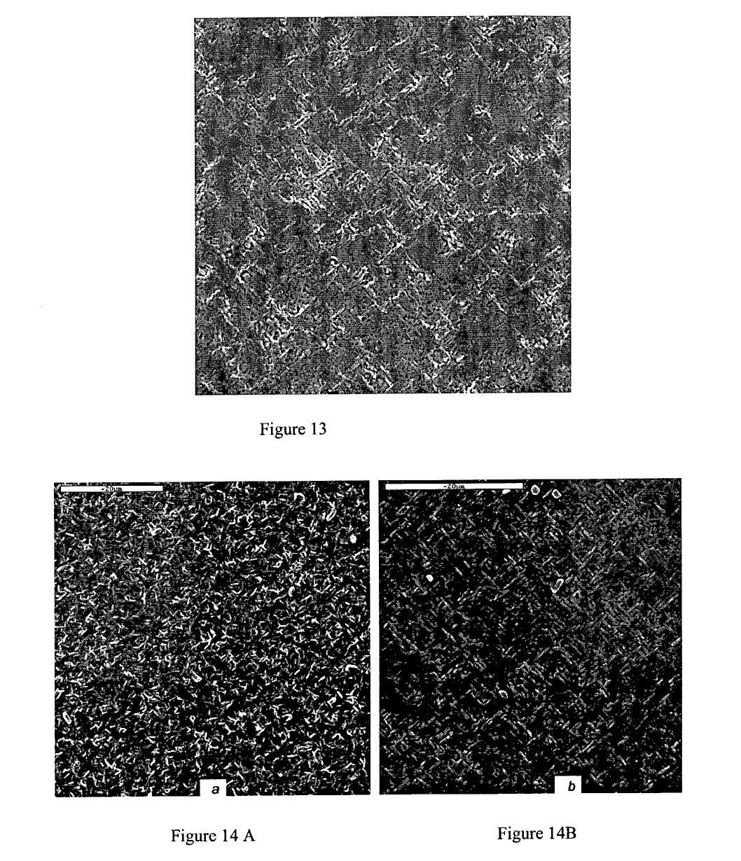

The first samples treated in the RTA furnace were deposited on LAO and YSZ single crystal substrates. The processing conditions and electrical properties are listed in Table 1. The partial pressure of water for these experiments was at least a factor of 10 lower than in the tube furnace. The reduction of the partial pressure of water had a significant effect on the orientation of the films. Sample 1 was grown without using the low/high process and still had a relatively high value of Jc, 1.1 MA/cm². The microstructure of another sample that was converted under the same conditions is shown in FIG. 13. The sample exhibited significant a-axis texturing. In order to determine the influence of PH₂O on growth rate, one of the samples (Sample 0) was converted at 10 mTorr for 5 minutes. After the conversion, residual BaF₂ peaks were observed in the x-ray pattern, indicating that the conversion was not complete and that the growth rate was significantly lower. Sample 2 was grown on a YSZ substrate under the same conditions except for use of the low/high process and exhibited a Jc of 2.24 MA/cm². This result shows that low speed of conversion during the initial stages of film growth reduces the amount of a-axis texturing and improves the Jc characteristics of thicker films.

Table 1 also shows that samples with film thicknesses up to 0.6 μm had very good electrical properties and very high growth rates. Sample 2 had a Jc of 2.24 MA/cm² and a growth rate of approximately 0.15 μm/min. Samples that were converted at atmospheric pressure at 785° C. under 0.22 Torr of moisture had a growth rate of 0.0017 μm/minute, 88 times less. The furnace temperature for the samples grown under reduced pressure was 50 degrees higher, but that difference cannot account for the entire increase in growth rate.

TABLE 1
Conditions for conversion under reduced pressure in the RTA furnace

| | | | | Low | | | | Total | | |
|---|---|---|---|---|---|---|---|---|---|---|
| Sample | Thickness, | | Temperature, | PH₂O, | High | PO₂, | Time, | Pressure, | | Jc, |
| I.D. | μm | Substrate | ° C. | mTorr | PH₂O | Torr | Low/High | Torr | Orientation | MA/cm² |
| 0 | 0.3 | YSZ | 835 | 2 | — | 7.7 | 5/0 | 7.7 | | — |
| 1 | 0.3 | LAO | 835 | 350 | 350 | 7.6 | 0/5 | 7.6 | | 1.1 |
| 2 | 0.3 | YSZ | 835 | 2 | 350 | 7.7 | 2/1 | 7.7 | | 2.24 |
| 3 | 0.3 | YSZ | 785 | 2 | 300 | 0.8 | 4/4 | 8.05 | | 4.2 |
| 4 | 0.5 | YSZ | 785 | 4 | 200 | 1 | 15/15 | 1 | | 1.2 |
| 5 | 0.5 | YSZ | 785 | 3 | 200 | 0.8 | 15/15 | 0.8 | | |
| 6 | 0.5 | YSZ | 785 | 2 | 200 | 1 | 15/15 | 1 | | |
| 7 | 0.5 | YSZ | 785 | 1 | 200 | 0.85 | 15/5 | 0.85 | | |
| 8 | 0.6 | YSZ | 785 | 2 | 300 | 0.8 | 10/15 | 8.05 | | 1.55 |
| 9 | 0.8 | YSZ | 835 | 2 | 300 | 7.6 | 2/5 | 7.6 | a-axis | |
| 10 | 0.8 | YSZ | 835 | 2 | 300 | 7.6 | 9/16 | 7.6 | a-axis | |
| 11 | 0.8 | YSZ | 835 | 2 | 300 | 7.6 | 15/10 | 7.6 | a-axis | |
| 12 | 0.8 | YSZ | 835 | 350 | 350 | 7.75 | 0/10 | 7.75 | random/a- | 0 |
| | | | | | | | | | axis | |

Jc decreases with increasing thickness of YBCO films because the amount of a-axis texturing increases with thickness [1]. We observed that a 0.8 μm thick YBCO film grown without the low/high process had zero Jc. A series of 0.8 μm thick YBCO films on YSZ was used to test whether the low/high process can be used to process thicker samples. FIG. 14 shows the microstructure of two samples (A-12; B-9) that were grown at 835° C. Sample 12 was grown without using the low/high process and exhibited zero Jc. Sample 9 was grown using the low/high process (3 mTorr of water for 2 minutes followed by 300 mTorr for 5 minutes). The estimated growth rate was 0.13 μm/min, using an assumption that the initial growth rate at 10 mTorr is much lower than growth rate at 300 mTorr. It is clear from FIG. 14 that the low/high process reduced the number of randomly oriented grains to zero and reduced the amount of a-axis texturing. It is also interesting to note that the microstructure of the thick film that was grown under low/high conditions is very similar to the microstructure of the thin film (Sample 1) that was grown at a constant partial pressure of water of 350 mTorr (FIG. 13).

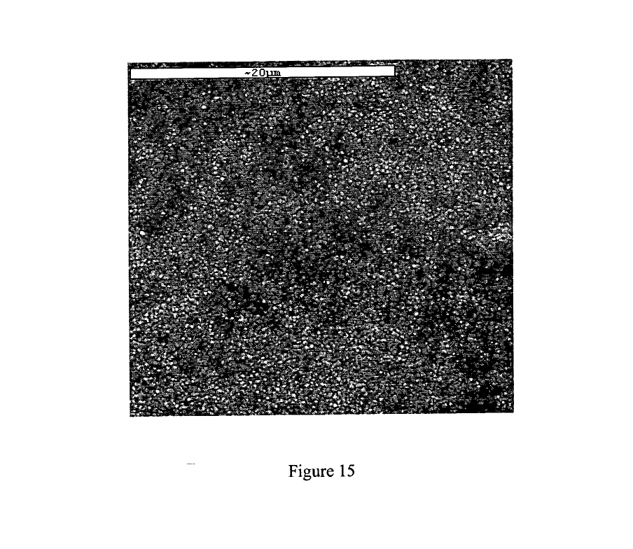

The last series of experiments was conducted using metal substrates, the preferred substrates for industrial applications. Table 2 shows that the techniques of the invention may be exploited for production of c-axis textured films on polycrystalline substrates. The growth rate for the conditions of P=1 Torr, T=785° C., and PH₂O=5 mTorr was determined by XRD. Samples were annealed for 3, 7 and 15 minutes and x-ray analysis was used to detect presence of residual BaF₂. The BaF₂ peak was not detected after approximately 7 minutes. This corresponds to the growth rate of about 1.9 nm/sec for a film thickness of 0.8 μm. Sample 80 was converted using the conditions presented in Table 2 and exhibited a Jc of 0.378 MA/cm². FIG. 15 shows that this sample has a strong c-axis texture. Samples 57 and 61 were exhibited Jc=0.471 and 0.113 MA/cm², respectively. Given the growth rate at the low total pressure used, these samples were probably entirely converted before introduction of the “high” moisture atmosphere. Still, the conversion rates of these samples are significantly higher than at atmospheric pressure. These results demonstrate that the techniques of the invention may be exploited to produce highly textured c-axis YBCO films at high growth rates.

TABLE 2
Conditions for conversion of 0.8 μm thick YBCO films on metal substrates

| | | Low | | | | Total | Heating | |
|---|---|---|---|---|---|---|---|---|
| Sample | Temperature, | PH₂O, | High | PO₂, | Time, | Pressure, | Rate, | |
| I.D. | ° C. | mTorr | PH₂O | Torr | Low/High | Torr | ° C./minute | Jc, MA/cm² |
| 48 | 785 | 6 | 300 | 1 | 15/15 | 1 | 392 | 1.19 |
| 57 | 785 | 5 | 300 | 0.3 | 15/15 | 3 | 392 | 0.471 |
| 58 | 785 | — | 200 | 0.2 | 0/28 | 2.1 | 392 | 0 |
| 61 | 785 | 5 | 200 | 0.2 | 10/8 | 2.1 | 392 | 0.113 |
| 72 | 785 | 5 | 250 | 1 | 15/15 | 1 | 78 | 0.925 |
| 73 | 785 | 4 | 250 | 1 | 15/15 | 1 | 392 | 0.7 |
| 74 | 785 | 5 | 250 | 1 | 33/0 | 1 | 78 | 0.975 |
| 75 | 785 | 5 | 150 | 0.9 | 15/15 | 0.9 | 785 | 0.625 |
| 76 | 785 | 6 | 340 | 1 | 15/15 | 1 | 785 | 0.8 |
| 78 | 785 | 5 | 300 | 1 | 15/15 | 1 | 392 | 0.813 |
| 79 | 785 | 5 | 200 | 1 | 15/7 | 1 | 785 | 0.775 |
| 80 | 785 | 5 | 150 | 1 | 1/3 | 1 | 392 | 0.378 |

One skilled in the art will recognize that the above methods may be optimized for different substrates and film thicknesses to maximize the Jc for a given superconductor composition and substrate. In addition, the total pressure is not critical for the formation of the c-axis texture. Rather, the total pressure determines the speed of the conversion. Higher pressures may be used where vacuum apparatus is not available or inconvenient, for example, for the preparation of oversized samples.

Other embodiments of the invention will be apparent to those skilled in the art from a consideration of the specification or practice of the invention disclosed herein. It is intended that the specification and examples be considered as exemplary only, with the true scope and spirit of the invention being indicated by the following claims.

1. A method of producing an oriented oxide superconducting film, comprising:
(a) providing a metal oxyfluoride film on a substrate, said metal oxyfluoride film comprising the constituent metallic elements of an oxide superconductor in substantially stoichiometric proportions;
(b) initiating convertion of the metal oxyfluoride into the oxide superconductor in a processing gas having a moisture content of less than 1% by mass and a total pressure less than atmospheric pressure for a time sufficient to form a layer of the oxide superconductor at the substrate/film interface; and
(c) completing conversion of the metal oxyfluoride into the oxide superconductor in a processing gas having a moisture content greater than that in step (b) and a total pressure less than atmospheric pressure.

2. The method of claim 1, wherein the moisture content in step (c) is between 4.5 and 35% by mass.

3. The method of claim 1, wherein the PH₂O during step (b) is less than 10 mTorr and the total pressure is about 8 Torr or less.

4. The method of claim 1, wherein the PH₂O during step (c) is between 150 and 350 mTorr and the total pressure is about 8 Torr or less

5. The method of claim 1, wherein the total pressure is less than about 8 Torr.

6. The method of claim 5, wherein the total pressure is less than about 1 Torr.

7. The method of claim 1, wherein the total pressure is less than about 0.1 Torr.

8. The method of claim 1, wherein the processing gas consists substantially of water vapor and oxygen.

9. The method of claim 1, further comprising depositing a buffer layer on the substrate before the step of depositing.

10. The method of claim 9, wherein the buffer layer comprises a member of yttria-stabilized zirconia, LaAlO₃, SrTiO₃, CeO₂, Y₂O₃, and MgO and any combination of the above.

11. The method of claim 1, wherein the film has a thickness of at least 0.3 μm.

12. The method of claim 11, wherein the film has a thickness of at least 0.5 μm.

13. The method of claim 12, wherein the film has a thickness of at least 0.8 μm.

14. The method of claim 13, wherein the film has a thickness of at least 1 μm.

15. The method of claim 1, wherein the superconductor comprises YBCO.

16. The method of claim 1, wherein the substrate comprises a ceramic.

17. The method of claim 16, wherein the ceramic is selected from the group consisting of YSZ, LaAlO₃, SrTiO₃, CeO₂, and MgO.

18. The method of claim 1, wherein the substrate comprises a metal having a texture selected from untextured, uniaxial texturing, and biaxial texturing.

19. The method of claim 18, wherein the metal is selected from steel, nickel, iron, molybdenum, copper, silver, and alloys and mixtures thereof.

20. A c-axis textured superconducting film fabricated by the steps of
(a) providing a metal oxyfluoride film on a substrate, said metal oxyfluoride film comprising the constituent metallic elements of an oxide superconductor in substantially stoichiometric proportions;
(b) initiating conversion of the metal oxyfluoride into the oxide superconductor in a processing gas having a moisture content of less than 5% by mass and a total pressure less than atmospheric pressure for a time sufficient to form a layer of the oxide superconductor at the substrate/film interface; and
(c) completing conversion of the metal oxyfluoride into the oxide superconductor in a processing gas having a moisture content greater than that in step (b) and a total pressure less than atmospheric pressure.

21. The c-axis textured superconducting film of claim 20, wherein the texture is biaxial.

22. The c-axis textured superconducting film of claim 20, wherein the film has a Jc greater than 0.45 MA/cm².

23. The c-axis textured superconducting film of claim 22, wherein the film has a Jc greater than 1 MA/cm².

24. The c-axis textured superconducting film of claim 23, wherein the film has a Jc greater than 2 MA/cm².

25. The c-axis textured superconducting film of claim 24, wherein the film has a Jc greater than 4 MA/cm².

26. The c-axis textured superconducting film of claim 20, wherein the moisture content in step (c) is between 4.5 and 34%.

27. The c-axis textured superconducting film of claim 20, wherein the PH₂O during step (b) is less than 10 mTorr and the total pressure is about 8 Torr or less.

28. The c-axis textured superconducting film of claim 20, wherein the PH₂O during step (c) is between 150 and 350 mTorr and the total pressure is about 8 Torr or less.

29. The c-axis textured superconducting film of claim 20, wherein the total pressure is less than about 8 Torr.

30. The c-axis textured superconducting film of claim 20, wherein the processing gas consists substantially of water vapor and oxygen.

31. The c-axis textured superconducting film of claim 20, wherein the substrate comprises a base and a buffer layer interposed between the base and the superconducting film.

32. The c-axis textured superconducting film of claim 31, wherein the buffer layer comprises a member of ceria, yttria-stabilized zirconia, yttrium oxide, and any combination of the above.

33. The c-axis textured superconducting film of claim 20, wherein the film has a thickness of at least 0.5 μm.

34. The c-axis textured superconducting film of claim 33, wherein the film has a thickness of at least 1 μm.

35. The c-axis textured superconducting film of claim 20, wherein the superconductor comprises YBCO.

36. The c-axis textured superconducting film of claim 20, wherein the substrate comprises a ceramic.

37. The c-axis textured superconducting film of claim 36, wherein the ceramic is selected from the group consisting of YSZ, LaAlO₃, SrTiO₃, CeO₂, and MgO.

38. The c-axis textured superconducting film of claim 20, wherein the substrate comprises a metal.

39. The c-axis textured superconducting film of claim 38, wherein the metal is selected from steel, nickel, iron, molybdenum, copper, silver, and alloys and mixtures thereof.

40. A method of producing an oriented oxide superconducting film, comprising:
(a) providing a metal oxyfluoride film on a substrate, said metal oxyfluoride film comprising the constituent metallic elements of an oxide superconductor in substantially stoichiometric proportions;
(b) converting the metal oxyfluoride into the oxide superconductor in a processing gas having a total pressure less than atmospheric pressure.

41. The method of claim 40, wherein the total pressure is less than about 8 Torr.

42. The method of claim 41, wherein the total pressure is less than about 1 Torr.

43. The method of claim 42, wherein the total pressure is less than about 0.1 Torr.

44. The method of claim 43, wherein the total pressure is less than about 0.01 Torr.

45. The method of claim 44, wherein the total pressure is less than about 0.01 Torr.

46. The method of claim 45, wherein the total pressure is less than about 0.001 Torr.

47. The method of claim 40, wherein the processing gas consists substantially of water vapor and oxygen.

48. The method of claim 40, further comprising depositing a buffer layer on the substrate before the step of depositing.

49. The method of claim 48, wherein the buffer layer comprises a member of yttria-stabilized zirconia, LaAlO₃, SrTiO₃, CeO₂, Y₂O₃, and MgO and any combination of the above.

50. The method of claim 40, wherein the film has a thickness of at least 0.3 μm.

51. The method of claim 50, wherein the film has a thickness of at least 0.5 μm.

52. The method of claim 51, wherein the film has a thickness of at least 0.8 μm.

53. The method of claim 52, wherein the film has a thickness of at least 1 μm.

54. The method of claim 40, wherein the superconductor comprises YBCO.

55. The method of claim 40, wherein the substrate comprises a ceramic.

56. The method of claim 55, wherein the ceramic is selected from the group consisting of YSZ, LaAlO₃, SrTiO₃, CeO₂, and MgO.

57. The method of claim 40, wherein the substrate comprises a metal having a texture selected from untextured, uniaxial texturing, and biaxial texturing.

58. The method of claim 57, wherein the metal is selected from steel, nickel, iron, molybdenum, copper, silver, and alloys and mixtures thereof.

59. The method of claim 40, wherein the film has a Jc greater than 0.45 MA/cm².

60. The method of claim 59, wherein the film has a Jc greater than 1 MA/cm².

61. The method of claim 60, wherein the film has a Jc greater than 2 MA/cm².

62. The method of claim 61, wherein the film has a Jc greater than 4 MA/cm².
